(19) United States
(12) Patent Application Publication
(10) Pub. No.: US 2024/0150887 A1
(43) Pub. Date: May 9, 2024

(54) METHOD OF MANUFACTURING ORDERED ARRANGEMENT OF GRAPHENE-CARBON NANO TUBE OF METAL SUBSTRATE AND COMPOSITE COATINGS FOR CARBON DEPOSIT

(71) Applicant: TRUSVAL TECHNOLOGY CO., LTD., MIAOLI COUNTY (TW)

(72) Inventor: SHIH-PAO CHIEN, MIAOLI COUNTY (TW)

(21) Appl. No.: 18/053,836

(22) Filed: Nov. 9, 2022

(51) Int. Cl. C23C 14/34; C01B 32/16; C01B 32/184; C01B 32/21; C23C 14/02; C23C 14/06; C23C 14/35

(52) U.S. Cl. CPC C23C 14/3414; C01B 32/16; C01B 32/184; C01B 32/21; C23C 14/021; C23C 14/025; C23C 14/028; C23C 14/0605; C23C 14/35

(57) ABSTRACT

The present invention relates to a method of manufacturing ordered arrangement of graphene-carbon nano tube of metal substrate and composite coatings for carbon deposit. The method comprises the steps of placing both sputtering targets and penetrating fluid into an evacuated penetrating oven; allowing the penetrating fluid to penetrate into the sputtering targets; placing each of the penetrated sputtering targets into an evacuated magnetic control sputtering machine; controlling the cooling water in the evacuated magnetic control sputtering machine, that is, performing an evacuated magnetic control sputtering process on a metal substrate, using the organometallic salt of the penetrating fluid to maintain non-magnetic properties before being decomposed below 150° C.; and decomposing particles of nano-organometallic salts at high temperature area after sputtering and depositing on the metal substrate, as a carbon catalyst, forming a carbon structure layer on the uneven rough parts of the metal substrate with carbon from the sputtering target.

### BACKGROUND OF THE PRESENT INVENTION

### Field of Invention

The present invention relates to a method of manufacturing ordered arrangement of graphene-carbon nano tube of metal substrate and aid composite coatings for carbon deposit, in particular to a method that is simpler and more convenient to manufacture and capable of saving manufacturing time and enhancing practical performance in overall implementation and use.

### Description of Related Arts

It is noted that with the vigorous development of high technology, the volume of electronic components tends to be miniaturized, and the density of electronic components per unit area is getting higher and higher, and its performance is continuously enhanced. Under these factors, the product quality requirements of electronic components are increasing almost year by year.

As far as the metal substrates of common electronic components are concerned, in the manufacturing process, the metal substrate is mainly placed in an erosion tank to clean the surface with chemicals, such as strong acid and alkali, to remove oil and rust, and after the chemicals are washed off in a neutralization tank and a cleaning tank, processed through several chemical tanks, so the surface of the aluminum foil is chemically etched and corroded to form a surface with many concave holes. Then it will be processed through an oxidation tank for neutralization cleaning and strong acid and electrochemical action to form a voltage-resistant oxide layer. Finally, the production process of the metal substrate will be completed by passing through a cleaning and neutralization tank and a drying tank.

However, although the above-mentioned method for manufacturing a metal substrate can achieve the expected effect of manufacturing the metal substrate, it is also found in the actual operation process that the metal substrate needs to go through a number of different tanks and several different steps in the production, which not only makes the steps extremely complicated and inconvenient, but also takes a relatively long production time, so that there is still room for improvement in the overall implementation.

Therefore, the inventor upholds many years of rich development and actual production experience in the related industry, and then conducts research and improvement to provide a method of manufacturing ordered arrangement of graphene-carbon nano tube of metal substrate and composite coatings for carbon deposit, for achieving the purpose of increasing the practical value thereof.

### SUMMARY OF THE PRESENT INVENTION

The main purpose of the present invention is to provide a method of manufacturing ordered arrangement of graphene-carbon nano tube of metal air substrate and composite coatings for carbon deposit, which is simpler and more convenient in manufacturing; and capable of saving manufacturing time and enhancing utility properties in its overall implementation and use.

### BRIEF DESCRIPTION OF THE DRAWINGS

FIG. 1 is a flow diagram of a production process of the present invention.

FIG. 2 is a perspective view of the structure of an evacuated penetrating oven according to the present invention.

FIG. 3 is a perspective view of a use state of the present invention applied to a plane evacuated magnetic control sputtering machine.

FIG. 4 is a perspective view of a use state of the present invention applied to a circular plane evacuated magnetic control sputtering machine.

FIG. 5 is a perspective view of a use state of the present invention applied to a cylindrical magnetic evacuated magnetic control sputtering machine.

FIG. 6 is a perspective view of an operation state of evacuated magnetic sputtering in an enhanced non-equilibrium closed magnetic field according to the present invention.

FIG. 7 is a perspective view of an operation state of evacuated aid magnetic sputtering in a large-scale multi-target non-equilibrium closed magnetic field according to the present invention.

FIG. 8 is a perspective view of another operation state of evacuated magnetic sputtering according to the present invention.

FIG. 9 is a perspective view of another operation state of evacuated magnetic sputtering of the present invention is illustrated.

FIG. 10 is a perspective view of a forming state of the present invention.

FIG. 11 is a perspective view of another forming state of the present invention.

FIG. 12 is a perspective view of another forming state of the present invention.

### DETAILED DESCRIPTION OF THE PREFERRED EMBODIMENT

In order to have a more complete and clear disclosure of the technical content used in the present invention, the purpose of the invention and the effect achieved, the present invention is described in detail below, referring to the disclosed drawings and drawing numbers:

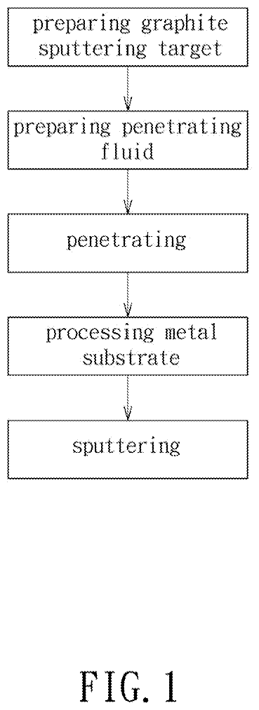

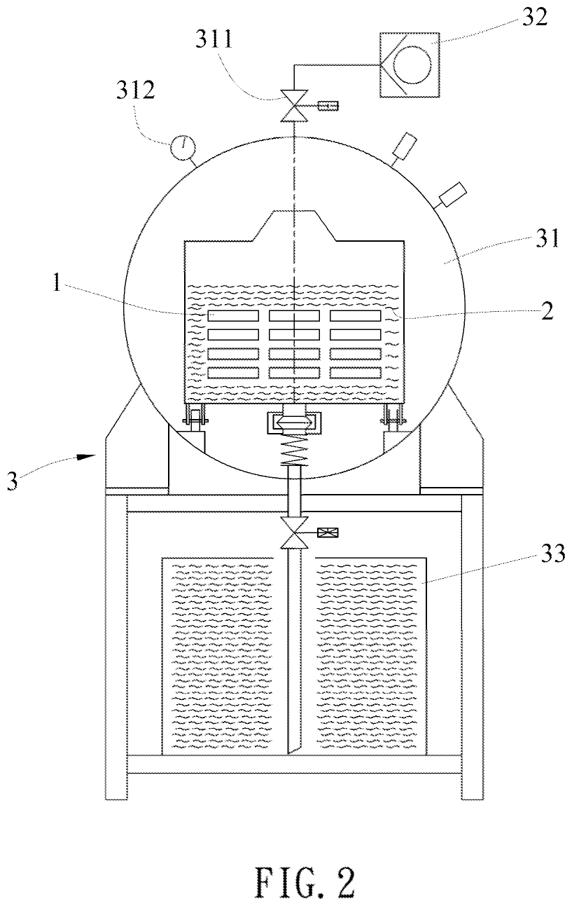

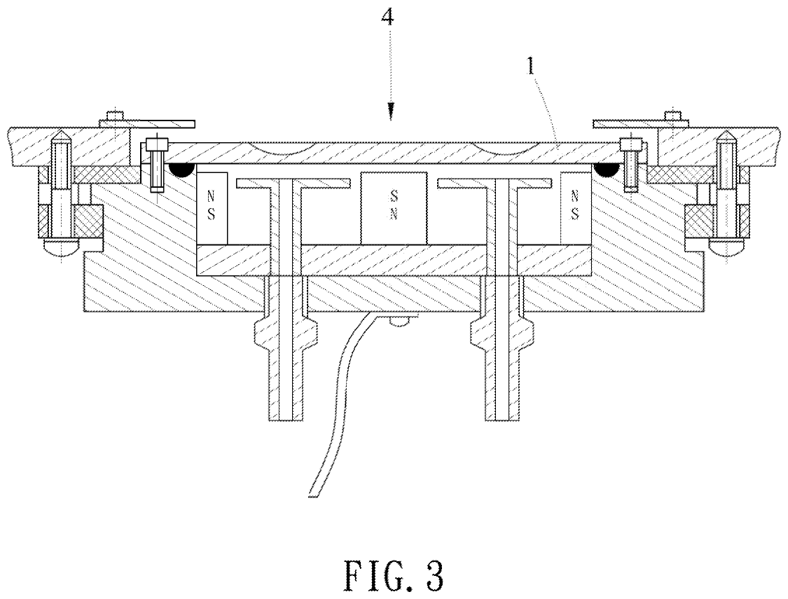

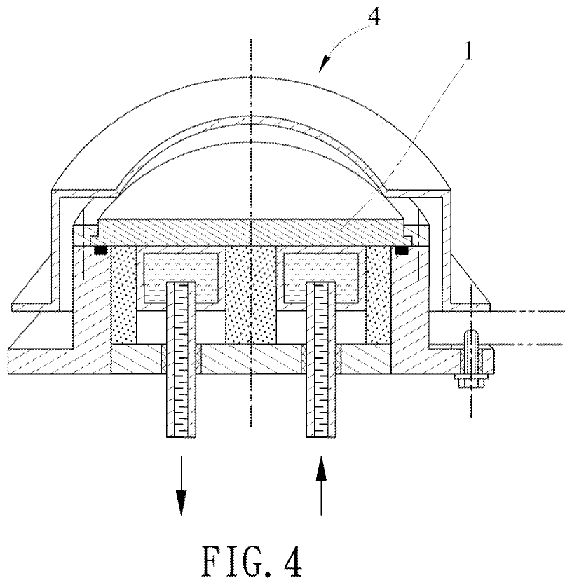

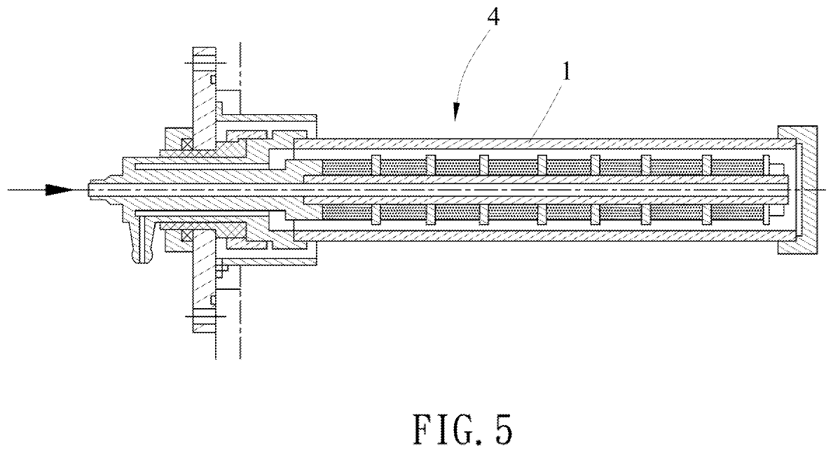

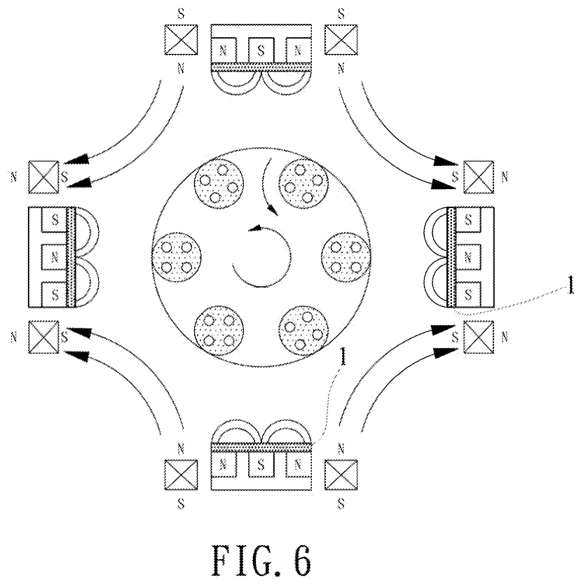

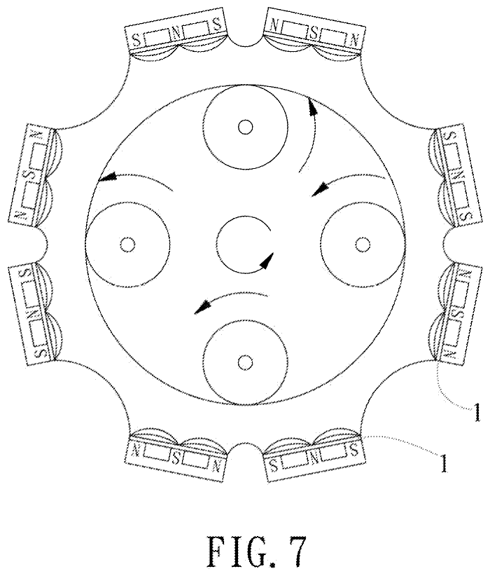

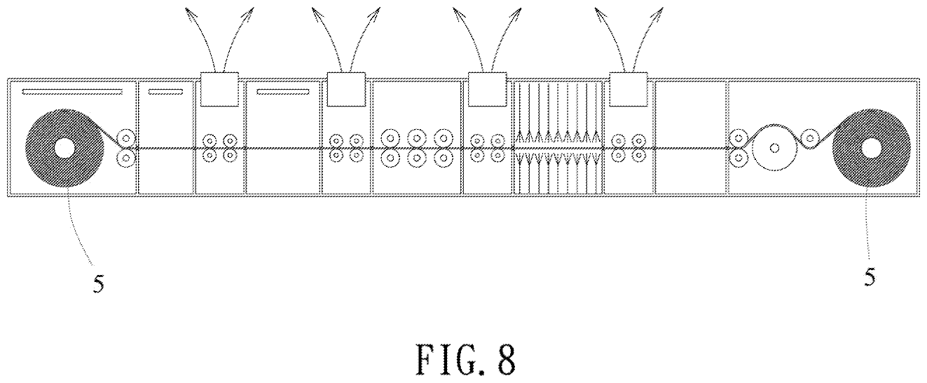

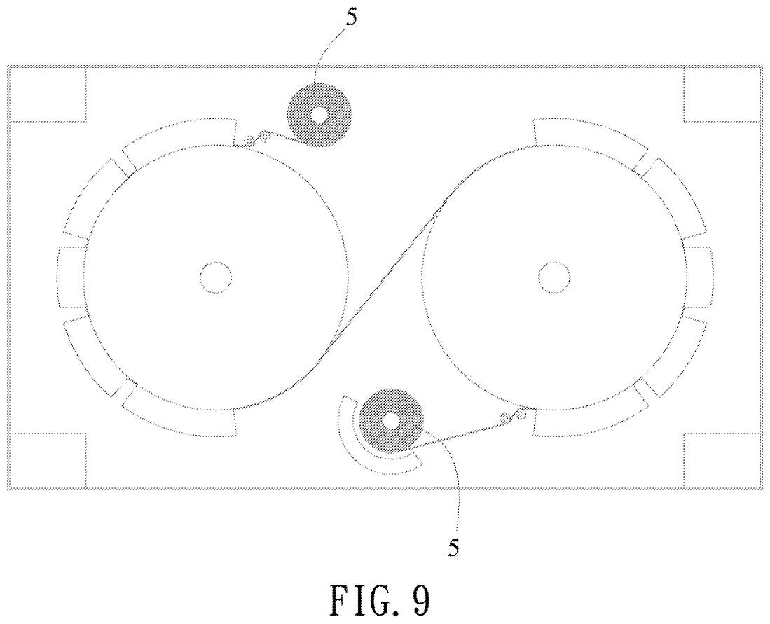

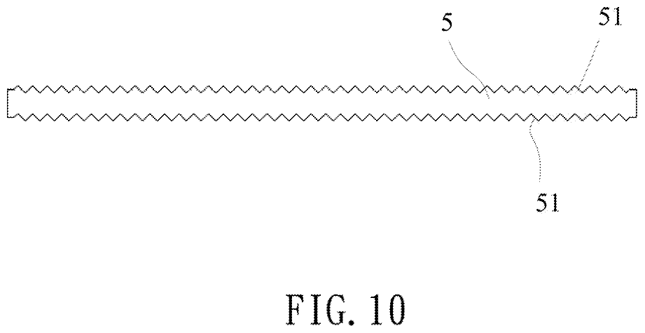

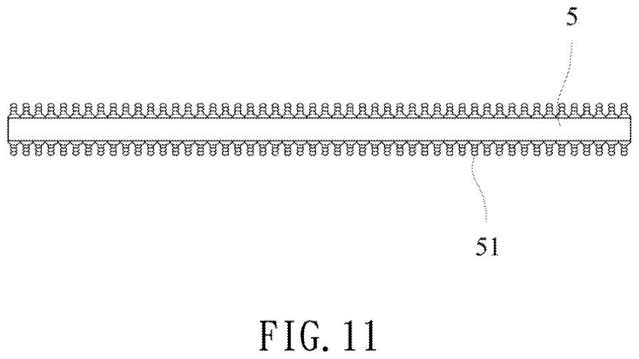

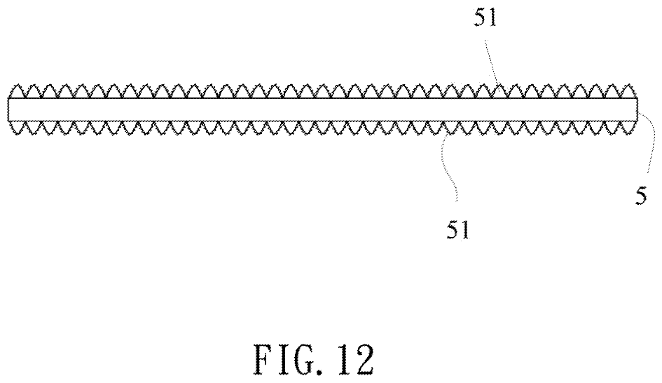

Referring to FIG. 1, a production flow diagram of the present invention is illustrated, wherein the present invention comprises the following steps:
A. preparing graphite sputtering target: manufacturing high-purity air graphite with graphite content 99.95% into magnetron sputtering targets of various geometric shapes, and controlling the porosity of the sputtering targets to be 15% to 30%;
B. preparing penetrating fluid: dissolving organometallic salt, such as iron, cobalt, nickel, etc., in an organic solvent until saturated so as to prepare the penetrating fluid;
C. penetrating: referring to FIG. 2, which illustrated a perspective view of the structure of an evacuated penetrating oven according to the present invention, placing the sputtering targets (1) and the penetrating fluid (2) in an evacuated penetrating oven (3), wherein the evacuated penetrating oven (3) has a furnace body (31) disposed thereon, wherein the furnace body (31) allows the sputtering targets (1) to be placed therein, arranging the penetrating fluid (2) to submerge the sputtering targets (1) in the furnace body (31), wherein the furnace body (31) has a vacuum valve (311) connected with an aft pressure control device (32), and a high vacuum pump of the air pressure control device (32) is used to evacuate the inside of the furnace body (31), wherein the furnace body (31) comprises a vacuum gauge (312) disposed thereon, which allows the air pressure value inside the furnace body (31) to be observed through the vacuum gauge (312), penetrating the penetrating fluid (2) into the sputtering targets (1) under a vacuum environment in the furnace body (31), and recycling the used penetrating fluid for reusing through a penetrating fluid recovery tank (33), wherein the penetrating fluid recovery tank (33) is connected with the furnace body (31);
D. processing metal substrate: subjecting a metal substrate (5) such as high-purity aluminum foil with an aluminum content of 99.7% or high-purity copper foil with a copper content of 99.7% for chemical rough plating or electrochemical corrosion or spraying or sputtering on both sides to form uneven rough parts on the surfaces of the metal substrate (5); and
E. sputtering: placing each of the sputtering targets (1) penetrated with the penetrating fluid (2) in an evacuated magnetic control sputtering machine (4), wherein the evacuated magnetic control sputtering machine (4) can be any one of a plane evacuated magnetic control sputtering machine, referring to FIG. 3, which illustrated a perspective view of a use state of the present invention applied to the plane evacuated magnetic control sputtering machine, a circular plane evacuated magnetic control sputtering machine, referring to FIG. 4, which illustrated a perspective view of a use state of the present invention applied to a circular plane evacuated magnetic control sputtering machine, and a cylindrical magnetic evacuated magnetic control sputtering machine, referring to FIG. 5, which illustrated a perspective view of a use state of the present invention applied to a cylindrical magnetic evacuated magnetic control sputtering machine, controlling the cooling air water in the evacuated magnetic control sputtering machine (4), so that the working temperature of a target surface of each sputtering target (1) is kept below 150° C., while the working temperature in a cavity of the evacuated magnetic control sputtering machine (4) is at least 300° C., and the vacuum degree is below 0.1 Pa, which allows evacuated magnetic sputtering on the metal substrate (5) processed in step D, referring to FIG. 6, which is a perspective view of an operation state of evacuated magnetic sputtering in an enhanced non-equilibrium closed magnetic field according to the present invention, referring to FIG. 7, which is a perspective view of an operation state of evacuated magnetic sputtering in a large-scale multi-target non-equilibrium closed magnetic field according to the present invention, referring to FIG. 8, which is another perspective view of an operation state of evacuated magnetic sputtering according to the present invention, and retelling to FIG. 9, which is another perspective view of an operation state of evacuated magnetic sputtering according to the present invention, sputtering the organometallic salts, such as: iron, cobalt, nickel, and etc., of the penetrating fluid (2), which is non-magnetic below 150° C. before being decomposed, to the high temperature area to decompose and release metal particles, such as iron, cobalt, nickel, etc., of the nano-organometallic salts to deposit on the metal substrate (5) and serve as the catalyst for the carbon, rapidly bonding the carbon atoms or carbon clusters continuously coming from the sputtering target (1) to form an ordered carbon structure and thrilling an ordered two-dimensional or three-dimensional carbon structure layer (51) of either a carbon nano tube grapheme or combination thereof on the entire or partial surface of the uneven rough parts of the metal substrate (5), referring to FIG. 10, a perspective view of a forming state of the present invention, FIG. 11, a perspective view of another forming state of the present invention, and FIG. 12, a perspective view of another forming state of the present invention, and controlling the length or sheet diameter of the carbon structure layer (51) formed on the metal substrate (5) through maintaining the working conditions of the evacuated magnetic control sputtering machine (4).

In this way, the metal substrate (5) can be applied to capacitor electrode foils, supercapacitor electrode foils, lithium battery electrodes, heat dissipation films, EMI heat dissipation films, and etc.

Based on the above disclosure of the use and implementation of the present invention, comparing with the prior arts, the present invention is simpler and more convenient in manufacturing, which can save the manufacture time, and enhance the effectiveness of the utility model in its overall implementation and use.

What is claimed is:

1. A method of manufacturing ordered arrangement of graphene-carbon nano tube of metal substrate and composite coatings for carbon deposit, comprising the steps of:
A. preparing graphite sputtering target: manufacturing graphite into magnetron sputtering targets of various geometric shapes;
B. preparing penetrating fluid: dissolving organometallic salts into an organic solvent until saturated so as to prepare the penetrating fluid;
C. penetrating: placing the sputtering targets and the penetrating fluid air in an evacuated penetrating oven, penetrating the penetrating fluid into the sputtering targets under a vacuum environment in the evacuated penetrating oven, wherein the evacuated penetrating oven has a furnace body disposed thereon, wherein the furnace body allows the sputtering targets to be placed therein, arranging the penetrating fluid to submerge the sputtering targets in the furnace body, wherein the furnace body has a vacuum valve connected with an air pressure control device, and a high vacuum pump of the air pressure control device is used to evacuate the inside of the furnace body, wherein the furnace body comprises a vacuum gauge disposed thereon, which allows the air pressure value inside the furnace body to be observed through the vacuum gauge;
D. processing metal substrate: forming uneven rough parts on both surfaces of a metal substrate; and
E. sputtering: placing each of the sputtering targets penetrated with the penetrating fluid into an evacuated magnetic control sputtering machine, controlling a cooling water in the evacuated magnetic control sputtering machine, performing evacuated magnetic sputtering on the metal substrate processed in step D, and sputtering the organometallic salts of the penetrating fluid, which is non-magnetic, below 150° C. before being decomposed, to the high temperature area to decompose and release metal particles of the nano-organometallic salts to deposit on the metal substrate and serve as the catalyst for the carbon, rapidly bonding the carbon from the sputtering target to form an ordered carbon structure and forming an ordered two-dimensional or three-dimensional carbon structure layer on the uneven rough parts of the metal substrate.

2. The method of manufacturing ordered arrangement of graphene-carbon nano tube of metal substrate and composite coatings for carbon deposit, as claimed in claim 1, wherein the graphite content of the sputtering target is ≥99.95%, and the porosity is 15%-30%.

3. The method of manufacturing ordered arrangement of graphene-carbon nano tube of metal substrate and composite coatings for carbon deposit, as claimed in claim 1, further comprising recycling the used penetrating fluid for reusing through a penetrating fluid recovery tank, wherein the penetrating fluid recovery tank is connected with the furnace body of the evacuated penetrating oven.

4. The method of manufacturing ordered arrangement of graphene-carbon nano tube of metal substrate and composite coatings for carbon deposit, as claimed in claim 1, wherein the metal substrate is selected from the group consisting of high-purity aluminum foil with aluminum content ≥99.7% and high-purity copper foil with copper content of 99.7%.

5. The method of manufacturing ordered arrangement of graphene-carbon nano tube of metal substrate and composite coatings for carbon deposit, as claimed in claim 4, wherein the uneven rough parts on the two surfaces of the metal substrate are provided through a process selected from the group consisting of chemical rough plating, electrochemical corrosion, spraying, and sputtering.

6. The method of manufacturing ordered arrangement of graphene-carbon nano tube of metal substrate and composite coatings for carbon deposit, as claimed in claim 1, wherein the uneven rough parts on the two surfaces of the metal substrate are provided through a process selected from the group consisting of chemical rough plating, electrochemical corrosion, spraying, and sputtering.

7. The method of manufacturing ordered arrangement of graphene-carbon nano tube of metal substrate and composite coatings for carbon deposit, as claimed in claim 1, wherein the evacuated magnetic control sputtering machine is selected from the group consisting of a plane evacuated magnetic control sputtering machine, a circular plane evacuated magnetic control sputtering machine, and a cylindrical magnetic evacuated magnetic control sputtering machine.

8. The method of manufacturing ordered arrangement of graphene-carbon nano tube of metal substrate and composite coatings for carbon deposit, as claimed in claim 1, wherein the working temperature of a target surface of the sputtering, target is kept below 150° C. at most, while the working temperature in a cavity of the evacuated magnetic control sputtering machine is at least 300° C., and the vacuum degree is below 0.1 Pa.

9. The method of manufacturing ordered arrangement of graphene-carbon nano tube of metal substrate and composite coatings for carbon deposit, as claimed in claim 1, wherein the organometallic salt is selected from the group consisting of iron, cobalt, and nickel.

10. The method of manufacturing ordered arrangement of graphene-carbon nano tube of metal substrate and composite coatings for carbon deposit, as claimed in claim 1, wherein the carbon structure layer formed on the uneven rough parts of the metal substrate is selected from the group consisting of a carbon nano tube, graphene, and combination thereof.
